(19) United States
(12) Patent Application Publication
(10) Pub. No.: US 2024/0266334 A1
(43) Pub. Date: Aug. 8, 2024

(54) Thermal Dissipation Structures and Methods for Forming Same

(71) Applicant: Taiwan Semiconductor Manufacturing Company, Ltd., Hsin-Chu (TW)

(72) Inventors: Ke-Gang Wen, Hsinchu (TW); Liang-Wei Wang, Hsinchu City (TW); Dian-Hau Chen, Hsinchu (TW); Tsung-Chieh Hsiao, Changhua County (TW)

(21) Appl. No.: 18/165,772

(22) Filed: Feb. 7, 2023

(51) Int. Cl. H01L 25/10; H01L 23/00; H01L 25/00; H10B 80/00

(52) U.S. Cl. CPC H01L 25/105; H01L 24/13; H01L 24/16; H01L 24/24; H01L 25/50; H10B 80/00; H01L 24/32; H01L 24/73; H01L 2224/13111; H01L 2224/13113; H01L 2224/13116; H01L 2224/13139; H01L 2224/13147; H01L 2224/13155; H01L 2224/16225; H01L 2224/24227; H01L 2224/32221; H01L 2224/73253; H01L 2225/1035; H01L 2225/1094

(57) ABSTRACT

An integrated semiconductor device is provided. The integrated semiconductor device includes a first semiconductor structure having a first IC, and a second semiconductor structure stacked above the first semiconductor structure and having a second IC. The second semiconductor structure has a first surface facing the first semiconductor structure and a second surface facing away from the first semiconductor structure. The integrated semiconductor device also includes a thermal dissipation structure having a first portion partially through the first IC and a second portion fully through the second semiconductor structure and exposed at the second surface of the second semiconductor structure. The second portion may be outside of the second IC.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Heat dissipation is a challenge in the 3D semiconductor devices because a 3D semiconductor device with increased chip density can exhibit high heat density and poor thermal dissipation performance. The heat generated in the inner die(s) of a 3D structure may be trapped in an inner region of a stacked structure and cause a sharp local temperature peak, sometimes referred to as a hot spot. Hot spots due to heat generated by devices may negatively affect the electrical performance of other overlaying devices in the stacked structure and often lead to electromigration and reliability issues for the 3D packages. There is a need to solve the above deficiencies and problems.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A illustrates a cross-sectional view of part of a 3D semiconductor device having a thermal dissipation structure, according to various aspects of the present disclosure.

FIG. 1B illustrates a top view of part of the 3D semiconductor device shown in FIG. 1A, according to various aspects of the present disclosure.

FIG. 2A illustrates a cross-sectional view of part of another 3D semiconductor device having a thermal dissipation structure, according to various aspects of the present disclosure.

FIG. 2B illustrates a top view of part of the 3D semiconductor device shown in FIG. 2A, according to various aspects of the present disclosure.

FIG. 3 illustrates a flowchart of an exemplary method for forming a 3D semiconductor device having a thermal dissipation structure, according to various aspects of the present disclosure.

FIGS. 4A-4J illustrate cross-sectional views of a 3D semiconductor device having a thermal dissipation structure during various stages of an exemplary fabrication process, according to various aspects of the present disclosure.

FIG. 5 illustrates a flowchart of an exemplary method for forming another 3D semiconductor device having thermal dissipation structures, according to various aspects of the present disclosure.

FIGS. 6A-6G illustrate cross-sectional views of another 3D semiconductor device having thermal dissipation structures during various stages of an exemplary fabrication process, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below.” “lower.” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

3D packaging have been used in various manufacturers and product lines to produce semiconductor devices with increased transistor density and higher speed. In a 3D semiconductor device, two or more semiconductor structures are stacked together. Devices, e.g., dies, in the stacked semiconductor structures are often surrounded by a molding compound and/or a dielectric material. The molding compound and/or the dielectric material can provide support or electric insulation between devices/structures. In 3D semiconductor devices, vias such as through-silicon vias (TSVs), through-dielectric vias (TDVs), and through-molding vias (TMVs) are often used to provide electrical connections between two or more stacked semiconductor structures. In semiconductor devices, a TSV is a vertical connection that passes through a silicon wafer or die, a TDV is a vertical connection that passes through a dielectric layer, and a TMV is a vertical connection that passes through a molding compound. However, thermal dissipation can be an issue in 3D semiconductor devices due to the low thermal conductivity of molding compound and/or dielectric materials (e.g., silicon oxide). For example, heat generated by dies embedded in molding compound or silicon oxide may be trapped and create hot spots during device operation. To cool the dies, a cooling medium is often placed on one side of the stacked semiconductor structures. The cooling medium can cool the devices/structures that are disposed sufficiently close to the cooling medium, such as the dies stacked on the top of the 3D structure. For the devices/structures (e.g., ICs) disposed not close enough from the cooling medium, such as the dies stacked at the bottom of the 3D structure, the cooling effect is greatly reduced due to lack of heat dissipation paths. The use of mere cooling medium is thus not enough to cool structures/devices that are distal to the cooling medium. As a result, heat densities in 3D semiconductor devices (e.g., in ICs that are far away from the cooling medium) can reach undesirably high and can be a real concern for device performance.

The present disclosure provides 3D semiconductor devices with improved thermal dissipation. The disclosed 3D semiconductor devices include at least a first semiconductor structure and a second semiconductor structure stacked together, and at least one thermal dissipation structure extending from the first semiconductor structure away from a cooling structure to the cooling structure. The heat dissipation structure may be at least partially through an IC in the first semiconductor structure. In an embodiment, the first semiconductor structure is separated from the cooling structure by at least the second semiconductor structure (or die) in between. The thermal dissipation structure may be routed around active devices in the 3D semiconductor device, and may be thermally coupled to the cooling structure, conducting heat from the IC (e.g., the further IC) to the cooling structure. The IC may thus be cooled. The first and second semiconductor structures are bonded together through direct bonding and/or an interposer. The thermal dissipation structure may extend through the bonding interface of the first and second semiconductor structures, or the interposer between the first and second semiconductor structures.

For example, a first semiconductor structure may include a first IC, and a second semiconductor structure may include a second IC. The first and second semiconductor structures may be bonded together. A cooling structure, e.g., a cooling medium, may be disposed over the second semiconductor structure. A thermal dissipation structure may extend at least partially through the first IC, fully through the second semiconductor structure, and may be thermally coupled to the cooling structure. The thermal dissipation structure may be disposed outside of the second IC. In various embodiments, the thermal dissipation structure may extend through the support material or insulating material around the second IC, such as dielectrics, silicon, and/or molding epoxy. The thermal dissipation structure may include a via in each of the first and second semiconductor structures. In an embodiment, the first and second semiconductor structures are bonded via an interposer, and the vias of the thermal dissipation structures are connected by an interconnect routing in the interposer. In another embodiment, the first and second semiconductor structures are bonded via direct bonding (e.g., at metal/dielectric surfaces), and the vias of the thermal dissipation structures are connected by one or more bonding contacts. In an embodiment, the vias of the heat dissipation structure each has a square cross-section, and includes a metal material such as copper.

To form a thermal dissipation structure, a first dissipation feature, including a first via, is formed in the first semiconductor structure. In an embodiment, the second semiconductor structure is bonded to the first semiconductor structure via an interposer, and an interconnect routing is formed in the interposer and connected to the first dissipation feature. A second thermal dissipation feature, including a second via, is formed on the interposer and connected to the interconnect routing. In an embodiment, the second via is formed by electroplating. A second IC is then bonded onto the interposer. A molding layer is then formed to encapsulate the second via and the second IC. In this embodiment, the first via, the second via, and the interconnect routing form a thermal dissipation structure. In an embodiment, the second semiconductor structure is bonded to the first semiconductor structure via direct bonding, and the first semiconductor structure may include a first thermal dissipation feature that includes the first via and a bonding contact landed on the first via. The second semiconductor structure may include a second IC and a support structure, bonded to the first IC at a bonding interface. A dielectric material may be deposited to fill the space between the second IC and the support structure. A second thermal dissipation structure, having a second via, may be formed in the dielectric material and aside the second IC. The second via may be in contact with the bonding contact of the first thermal dissipation structure at the bonding interface. In this embodiment, the first via, the respective bonding contact, and the second via, may form a heat dissipation structure. In an embodiment, the first semiconductor structure includes a third thermal dissipation feature that includes a third via and a bonding contact landed on the third via. A fourth thermal dissipation feature, extending in the support structure, may include a fourth via and a bonding contact landed on the fourth via. The bonding contacts of the third and fourth thermal dissipation features are in contact with each other at the bonding interface. In this embodiment, the third and fourth vias, and the respective bonding contacts may form a heat dissipation structure. A cooling structure is then attached to the bonded first and second semiconductor structures, e.g., over the second semiconductor structure. The cooling structure may include a cooling medium, such as water, and optionally a carrier wafer. The thermal dissipation structures may be thermally coupled to the cooling medium to conduct/dissipate heat generated in the first IC.

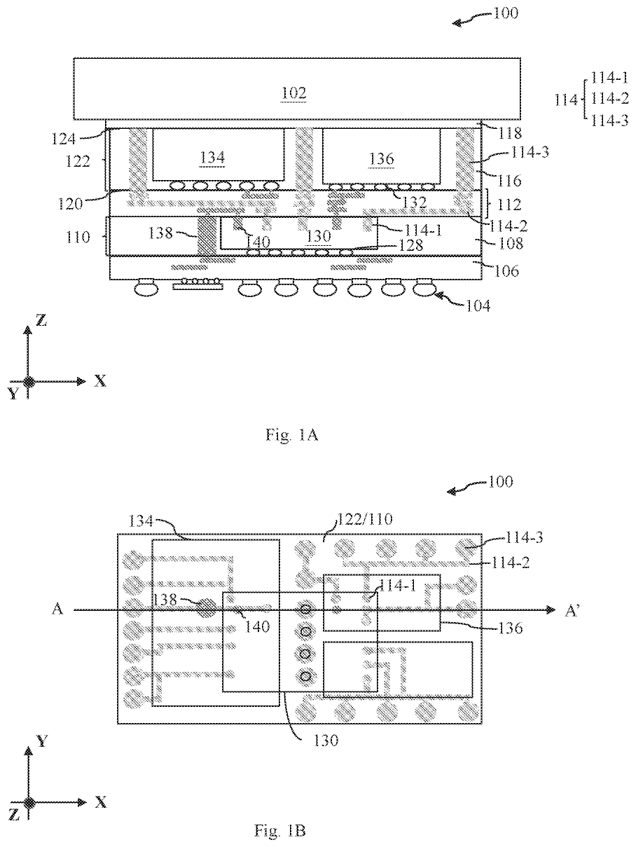

FIGS. 1A and 1B illustrate a 3D semiconductor device 100 having an exemplary thermal dissipation structure, according to an embodiment of the present disclosure. FIG. 1B illustrates a top view of 3D semiconductor device 100, and FIG. 1A illustrates a cross-sectional view of 3D semiconductor device 100 along the A-A′ direction shown in FIG. 1B. For case of illustration, FIG. 1B shows the layout of the ICs in 3D semiconductor device 100 and the distribution of the heat dissipation structures. It should be noted that, FIGS. 1A and 1B may only show a partial view of 3D semiconductor device 100, in an embodiment.

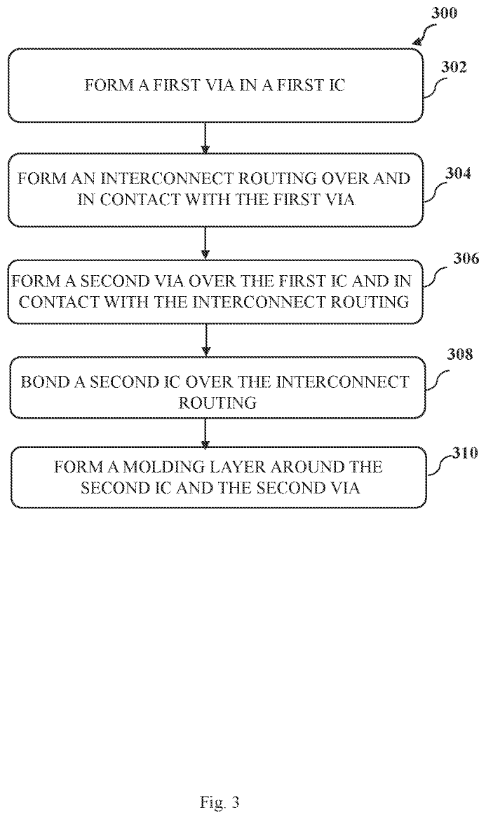

As shown in FIGS. 1A and 1B, 3D semiconductor device 100 may include a first semiconductor structure 110, an interposer 112, a second semiconductor structure 122, a redistribution structure 106, and a cooling structure 102. First semiconductor structure 110 and second semiconductor structure 122 may be bonded via interposer 112. Cooling structure 102 may be attached/bonded to second semiconductor structure 122 via an adhesive layer 118. As shown in FIGS. 1A and 1B, first semiconductor structure 110 may include IC 130, and second semiconductor structure 122 may include IC 134 and IC 136.

Redistribution structure 106 is disposed over the first surface (e.g., bottom surface) of 3D semiconductor device 100. Redistribution structure 106 provides electrical connection between first semiconductor structure 110 and an external circuit through soldering features 104 and 128. In some embodiments, redistribution structure 106 includes one or more soldering features 104 for bonding 3D semiconductor device 100 onto another structure, e.g., a package substrate. Redistribution layer structure 106 may include a plurality of polymer layers and a plurality of redistribution layers stacked alternatingly. In some embodiments, the topmost redistribution layer is also referred to as an under-ball metallurgy (UBM) layer for ball mount. In some embodiments, each of the polymer layers includes polybenzoxazole (PBO), polyimide, benzocyclobutene (BCB), a combination thereof, or the like. In some embodiments, each of the redistribution layers includes copper, nickel, titanium, a combination thereof, or the like, and is formed by an electroplating process. Redistribution structure 106 may also be referred to as a first integrated fan-out layer InFO layer.

Soldering features 104, e.g., also referred to as balls or bumps, are disposed respectively on the side of redistribution structure 106 that is facing away from IC 130. In some embodiments, soldering features 104 are electrically connected to redistribution structure 106 (e.g., the metallization layers of redistribution structure 106). Soldering features 104 may provide electrical connection between 3D semiconductor device 100 and another package substrate that is attached to (e.g., soldered to) soldering features 104. In some embodiments, soldering features 104 include a conductive material with low resistivity, such as Sn, Pb, Ag, Cu, Ni, Bi and/or an alloy.

First semiconductor structure 110 may include, besides IC 130, soldering features 128, a plurality of vias, and a molding layer 108. Soldering features 128 are disposed between redistribution structure 106 and IC 130. In some embodiments, soldering features 128 are electrically connected to redistribution structure 106 and IC 130, providing electrical connection between IC 130 and redistribution structure 106. In some embodiments, soldering features 128 include a conductive material with low resistivity, such as Sn, Pb, Ag, Cu, Ni, Bi and/or an alloy.

Molding layer 108 may surround IC 130 and encapsulate the structures/devices above redistribution structure 106. Molding layer 108 may provide support and insulation for IC 130. In some embodiments, molding layer 108 may include molding epoxy, a nitride such as silicon nitride, an oxide such as silicon oxide, phosphosilicate glass (PSG), borosilicate glass (BSG), boron-doped phosphosilicate glass (BPSG), phenolic hardener, silica, pigment, and/or a combination thereof.

IC 130 may be any suitable die. For example, IC 130 may be a logic die, a system-on-chip (SOC) die, a memory die, or a combination. In an embodiment, IC 130 includes a plurality of front-end-of-line (FEOL) devices such as transistors, capacitors, memory cells, etc. IC 130 may also include interconnect structures for connecting the FEOL devices with vias such as TSV 140. For example, IC 130 may also include various middle-end-of-line (MEOL) structures and back-end-of-line (BEOL) structures. In an embodiment, TSV 140 may be electrically connected to a respective FEOL device through a MEOL/BEOL structure.

First semiconductor structure 110 may include a plurality of vias (e.g., 138, 140, and 114-1) for signal transmission and heat dissipation. For example, vias such as one or more TMVs 138 and one or more TSVs 140 may provide further electrical connection between IC 130 and redistribution structure 106. TMV 138 may extend through molding layer 108 and be electrically connected to redistribution structure 106. TSV 140 may extend at least partially through IC 130 and be electrically connected to active devices in IC 130. TSV 140 and TMV 138 may be electrically connected to each other by an interconnect routing in interposer 112. In some embodiments, TMV 138 and TSV 140 may include a conductive material such as copper, tungsten, aluminum, and/or a combination or an alloy. In some embodiments, TMV 138 and TSV 140 may each have a round cross-section (e.g., in the x-y plane).

Vias 114-1 may be part of a thermal dissipation structure for dissipating heat from IC 130. Via 114-1 may extend at least partially in IC 130. Vias 114-1 may also be referred to as thermal TSVs, or denoted as tTSVs. In an embodiment, via 114-1 may have the same length/depth (e.g., in the z-direction) as TSV 140. Different from TSV 140, via 114-1 may not be electrically connected to any active components in IC 130, and may have a square cross-section. In an embodiment, the side length of via 114-1 (e.g., having a square cross-section) may be the same as the diameter of TSV 140 (e.g., having a round cross-section), such that via 114-1 has a larger cross-sectional area (e.g., greater than TSV 140) which facilitates heat dissipation. In an embodiment, one end of via 114-1 is in contact with (e.g., embedded in) a dielectric material in IC 130, and the other end of via 114-1 is in contact with interposer 112 (e.g., a respective interconnect routing in interposer 112). Particularly, one end of via 114-1 may be positioned through or nearby a thermal hot spot identified in IC 130. Via 114-1 may include the same material as TMV 138/TSV 140. For example, via 114-1 may include a conductive material such as copper, tungsten, aluminum, and/or a combination or an alloy.

Interposer 112 may be in contact with the first semiconductor structure 110. In an embodiment, a first surface of interposer 112 is in contact with the second surface of first semiconductor structure 110. Interposer 112 may include interconnect routings embedded in one or more layers of insulating material. The interconnect routings may transmit electrical signals and conduct heat from IC 130. The insulating material may include epoxy, polyimide, silicon, glass, or a combination thereof. The interconnect routings may include a conductive material such as copper, tungsten, aluminum, and/or a combination or an alloy. As shown in FIG. 1A, interposer 112 may include an interconnect routing that connects (e.g., in contact with) TMV 138 and TSV 140 for signal transmission. Interposer 112 may also include an interconnect routing that connects the soldering features in second semiconductor structure 122 with TSV 140 in IC 130. In an embodiment, interposer 112 includes an interconnect routing 114-2 that is connected to (e.g., in contact with or thermally coupled to) via 114-1. Interconnect routing 114-2 may conduct heat from IC 130 through via 114-1. Interposer 112 may also be referred to as a second InFO layer.

A first surface 120 of second semiconductor structure 122 may be in contact with the second surface of interposer 112. Second semiconductor structure 122 may include one or more ICs (e.g., 134 and 136), a molding layer 116, a plurality of soldering features 132, and one or more vias 114-3.

Molding layer 116 may surround ICs 134 and 136 and encapsulate structures/devices above interposer 112. Molding layer 116 may provide support and insulation for ICs 134 and 136. In some embodiments, molding layer 116 may include molding epoxy, a nitride such as silicon nitride, an oxide such as silicon oxide, phosphosilicate glass (PSG), borosilicate glass (BSG), boron-doped phosphosilicate glass (BPSG), and/or a combination thereof.

ICs 134 and 136 may each be any suitable die. ICs 134 and 136 may each be partially overlapped with IC 130 in the x-y plane. For example, ICs 134 and 136 may each be a logic die, a system-on-chip (SOC) die, a memory die, or a combination. In an embodiment, ICs 134 and 136 each includes a plurality of FEOL devices such as transistors, capacitors, memory cells, etc. ICs 134 and 136 may also include interconnect structures for connecting the FEOL devices with the interconnect routings in interposer 112 through soldering features 132. For example, ICs 134 and 136 may also include various MEOL structures and BEOL structures. In an embodiment, IC 134 is a dynamic random-access memory (DRAM) chip/die.

Soldering features 132 are disposed on the first side of second semiconductor structure 122. In some embodiments, soldering features 132 are electrically connected to interposer 112. Soldering features 132 may provide electrical connection between ICs 134/136 and interposer 112. In some embodiments, soldering features 132 include a conductive material with low resistivity, such as Sn, Pb, Ag, Cu, Ni, Bi and/or an alloy. Electrical signals may be transmitted between IC 134/136 and IC 130 through soldering features 132, interposer 112, and TSVs 140.

Vias 114-3 may be part of a thermal dissipation structure for dissipating heat from IC 130. Via 114-3 may extend fully in second semiconductor structure 122 (i.e., in molding layer 116) and may be located outside ICs 134 and 136. For example, via 114-3 may be located between ICs 134 and 136, or aside from ICs 134 and 136. Vias 114-3 may also be referred to as thermal TMVs, or denoted as tTMVs. Via 114-3 may be connected to (e.g., in contact with) interconnect routing 114-2 that is connected/thermally coupled to via 114-1. In an embodiment, via 114-1 is connected to one end of interconnect routing 114-2, and via 114-3 is connected to another end (or the other end) of interconnect routing 114-2. Different from TMV 138, via 114-3 may not be electrically connected to any active components in second semiconductor structure 122 or IC 130, and may be in contact with (e.g., embedded in) molding layer 116. In an embodiment, via 114-3 may each have a square cross-section. The side length of via 114-3 (e.g., having a square cross-section) may be the same as the diameter of TMV 138 (e.g., having a round cross-section)), such that via 114-3 has a larger cross-sectional area (e.g., than TSV 140) which facilitates heat dissipation. Further, the side length of via 114-3 may be larger than that of via 114-1. Via 114-3 may include the same material as TMV 138/TSV 140. For example, via 114-3 may include a conductive material such as copper, tungsten, aluminum, and/or a combination or an alloy.

In an embodiment, one via 114-1 may be connected to (e.g., in contact with or thermally coupled to) one interconnect routing 114-2, and one interconnect routing 114-2 may be further connected to (e.g., in contact with or thermally coupled to) one or more vias 114-3. The connected via(s) 114-1, interconnect routing 114-2, and via(s) 114-3 may together be referred to as a thermal dissipation structure 114. In an embodiment, as shown in FIG. 1B, when interconnect routing 114-2 is connected to a single via 114-3 and a single via 114-1, the respective via 114-1, the interconnect routing 114-2, and the respective via 114-3 may together be referred to as a thermal dissipation structure 114. In another embodiment, when one interconnect routing 114-2 is connected to a plurality of vias 114-3 and a single via 114-1, the respective via 114-1, the interconnect routing 114-2, and the respective plurality of vias 114-3 may together be referred to as a thermal dissipation structure 114. In yet another embodiment, when one interconnect routing 114-2 is connected to a plurality of vias 114-3 and a plurality of vias 114-1, the respective plurality of vias 114-1, the interconnect routing 114-2, and the respective plurality of vias 114-3 may together be referred to as a thermal dissipation structure 114. In various embodiments, depending on the locations of via 114-1(s) and via(s) 114-3 of thermal dissipation structure 114, the length, path, and the location of the respective interconnect routing 114-2 may be flexible designed. For example, interposer 112 may include interconnect routings 114-2 of various lengths and depths (e.g., in the z-direction) to accommodate the distribution of vias 114-1 and 114-3. In an embodiment, vias 114-1 and 114-3 may each be located in areas where no active device is formed. Depending on the layout of devices/structures of second semiconductor structure 122, in various embodiments, vias 114-3 may be flexibly disposed between ICs 134 and 136, and/or in the peripheral area of 3D semiconductor device 100.

Cooling structure 102 may be disposed over a second surface 124 of second semiconductor structure 122. Cooling structure 102 may include a water package or any suitable packaged cooling material. In an embodiment, cooling structure 102 may be attached to second semiconductor structure 122 via an adhesive layer 118 such as thermal glue. Adhesive layer 118 may have desirable thermal conductivity such that vias 114-3 (or thermal dissipation structures) are thermally coupled to cooling structure 102. Heat generated in IC 130 may then be conducted to cooling structure 102 by thermal dissipation structure 114, and IC 130 may be cooled.

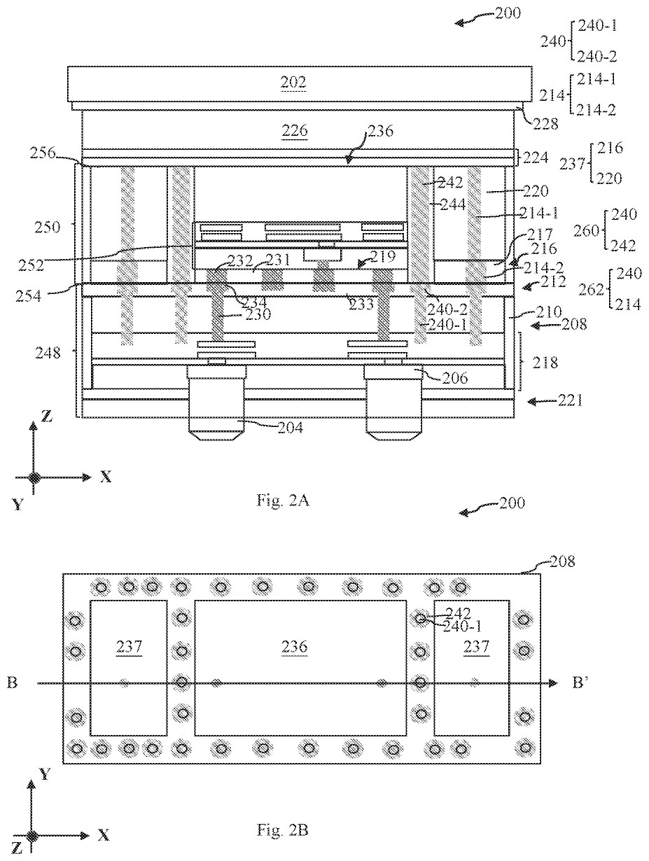

FIGS. 2A and 2B illustrate a 3D semiconductor device 200 having exemplary thermal dissipation structures, according to an embodiment of the present disclosure. FIG. 2B illustrates a top view of 3D semiconductor device 200, and FIG. 2A illustrates a cross-sectional view of 3D semiconductor device 200 along the B-B′ direction shown in FIG. 2B. For ease of illustration, FIG. 2B shows the layout of the ICs in 3D semiconductor device 200 and the distribution of the heat dissipation structures. It should be noted that, FIGS. 2A and 2B may only show a partial view of 3D semiconductor device 200, in an embodiment.

As shown in FIGS. 2A and 2B, 3D semiconductor device 200 may include a first semiconductor structure 248 and a second semiconductor structure 250. Optionally, 3D semiconductor device 200 includes a cooling structure. First semiconductor structure 248 and second semiconductor structure 250 may be bonded at a bonding interface 254. The cooling structure may be attached/bonded to second semiconductor structure 250 via one or more adhesive layers 224.

First semiconductor structure 248 may include an IC 208, a bonding layer 212 over IC 208, a plurality of vias through IC 208, one or more first heat dissipation features 240, a bonding layer 212, and one or more connecting structures 204 coupled to interconnect structure 218.

IC 208 may be any suitable die. For example, IC 208 may be a logic die, a system-on-chip (SOC) die, a memory die, or a combination. In an embodiment, IC 208 includes a plurality of FEOL devices such as transistors, capacitors, memory cells, etc. IC 208 may also include an interconnect structure 218 electrically connected to the FEOL devices/structures. For example, interconnect structure 218 may include various MEOL structures and BEOL structures. In an embodiment, interconnect structure 218 may be a bottom portion of IC 208 away from the second semiconductor structure 250. In an embodiment, IC 208 may be isolated from other devices/ICs by a spacer 210. Spacer 210 may include any suitable insulating material such as silicon oxide, silicon nitride, silicon oxynitride, spin-on glass (SOG), and/or epoxy.

Interconnect structure 218 may include a plurality of metallization layers. The metallization layers of interconnect structure 218 are embedded in a plurality of intermetal dielectric (IMD) layers that may be formed of low-k (LK) or extreme low-k (ELK) dielectric materials. Example low-k dielectric materials may include Phosphosilicate Glass (PSG), Boroilicate Glass (BSG), Boron-Doped Phosphosilicate Glass (BPSG), Fluorine-Doped Silicate Glass (FSG), Tetraethyl orthosilicate (TEOS). Example ELK dielectric materials include porous organosilicate glass. The metallization layers may include copper (Cu) or titanium nitride (TiN). The metallization layers may be electrically connected to a contact pad 206, which may include of aluminum (Al) or aluminum copper (Al—Cu) and may be referred to as an aluminum pad. Contact pad 206 may each be electrically connected to an under-bump metallization (UBM) feature which can further be electrically connected to an external circuit/device.

A UBM feature may be disposed in contact with contact pad 206, and may include multiple layers, such as a barrier layer, a seed layer and a metal bump. In some embodiments, The UBM feature may include titanium, titanium nitride, nickel, cupronickel, cobalt, copper, or a combination thereof. A soldering feature may be formed in contact with the UBM feature. In some embodiments, the soldering feature may include Pb, Sn, InSb, tin, silver, copper, or a combination thereof. The UBM feature and soldering feature may be collectively referred to as a connecting structure 204. Connecting structure 204 may further be in contact with a package substrate. Electrical signals may be transmitted from connecting structures 204 to interconnect structure 218. In an embodiment, first semiconductor structure 248 may also include one or more passivation layers 221 over interconnect structure 218 and insulating the connecting structures 204. The one or more passivation layers 221 may include a suitable insulating material such as silicon oxide, silicon nitride, silicon oxynitride, polyimide, and/or epoxy.

First semiconductor structure 248 may include a plurality of vias extending partially through IC 208. The vias may be at least in contact with bonding layer 212. In some embodiments, the vias extend partially in bonding layer 212. The vias may be electrically connected to interconnect structure 218 (e.g., the metallization layers in interconnect structures 218) and bonding layer 212 (e.g., the bonding contacts in bonding layer 212). For example, first semiconductor structure 248 may include a plurality of TSVs 230. TSV 230 may transmit electrical signals from interconnect structure 218 to bonding layer 212, and further to second semiconductor structure 250. In some embodiments, TSV 230 may include a conductive material such as copper, tungsten, aluminum, and/or a combination or an alloy. In some embodiments, TSV 230 may have a round cross-section (e.g., in the x-y plane).

IC 208 may also include a plurality of vias 240-1, each partially embedded in IC 208. Via 240-1 may be part of a thermal dissipation structure for dissipating heat from IC 208. Via 240-1 may be position though or nearby a heat hot spot identified in IC 208. Via 240-1 is also referred to as thermal TSV, or denoted as tTSV. In an embodiment, via 240-1 may have the same length/depth (e.g., in the z-direction) as TSV 230. Different from TSV 230, via 240-1 may not be electrically connected to any active components in first semiconductor structure 248, and may have a square cross-section. The side length of via 240-1 may be the same as the diameter of TSV 230 (e.g., having a round cross-section), such that via 240-1 has a larger cross-sectional area (e.g., than TSV 230) which facilitates heat dissipation. In an embodiment, via 240-1 is in contact with (e.g., embedded in) dielectric materials in IC 208. In an embodiment, one end of via 240-1 may be in contact with the dielectric materials in interconnect structure 218, and the other end of via 240-1 may be in contact with a respective bonding contact. Via 240-1 may include the same material as TSV 230. For example, via 240-1 may include a conductive material such as copper, tungsten, aluminum, and/or a combination or an alloy.

Bonding layer 212 may be disposed over and in contact with IC 208 and may be electrically connected to interconnect structure 218. Bonding layer 212 may include a plurality of bonding contacts (e.g., 234, 240-2) distributed in a dielectric layer 233. Dielectric layer may include any suitable dielectric material such as silicon oxide, silicon nitride, silicon oxynitride, and/or spin-on glass (SOG). As shown in FIG. 2A, bonding layer 212 may include one or more bonding contacts 234 each landed on (e.g., in contact with) a TSV 230. Bonding contact 234 may be in contact with bonding interface 254 and may transmit electrical signals from TSV 230 to second semiconductor structure 250. In an embodiment, bonding contact 234 is in contact with another bonding contact of second semiconductor structure 250 at bonding interface 254. Bonding contact 234 may include a conductive material such as copper, tungsten, aluminum, and/or a combination or an alloy.

Bonding layer 212 may also include a plurality of bonding contacts 240-2 distributed in dielectric layer 233. Bonding contacts 240-2 may be part of a heat dissipation structure for dissipating heat from IC 208. Bonding contacts 240-2 may each be landed on (e.g., in contact with) a respective via 240-1 on one end. The other end of each of bonding contacts 240-2 may be in contact with bonding interface 254. Heat generated in IC 208 may be transmitted to bonding contacts 240-2 through via 240-1. In an embodiment, bonding contacts 240-2 and 234 may have about the same dimensions, and may have the same material. In an embodiment, bonding contact 240-2 and a respective via 240-1 may together be referred to as a first thermal dissipation feature 240.

Second semiconductor structure 250 may include an IC 236, one or more support structures 237 aside from IC 236, one or more second thermal dissipation features 242, a bonding layer 219, and one or more third thermal dissipation feature 214. In an embodiment, a first surface of second semiconductor structure 250 may be facing first semiconductor structure 248 and may be bonded to first semiconductor structure 248 at bonding interface 254. A second surface 256 of second semiconductor structure 250 may be facing away from first semiconductor structure 248.

IC 236 may be any suitable die. For example, IC 236 may be a logic die, a system-on-chip (SOC) die, a memory die, or a combination. In an embodiment, IC 236 includes a plurality of FEOL devices such as transistors, capacitors, memory cells, etc. IC 236 may also include an interconnect structure 252 electrically connected to the FEOL devices/structures. For example, interconnect structure 252 may also include various MEOL structures and BEOL structures. In an embodiment, the FEOL devices/structures in IC 236 may be electrically connected to the metallization layers in interconnect structure 218. In an embodiment, interconnect structure 252 may be a bottom portion of IC 236. In an embodiment, IC 236 may be isolated from other devices/ICs by a dielectric material such as a dielectric layer 244 (description in below). As shown in FIG. 2B, in an embodiment, the projection of IC 236 may completely fall in the projection of IC 208 in the x-y plane.

Interconnect structure 252 may include a plurality of metallization layers. The metallization layers of interconnect structure 252 are embedded in a plurality of intermetal dielectric (IMD) layers that may be formed of low-k (LK) or extreme low-k (ELK) dielectric materials. Example low-k dielectric materials may include Phosphosilicate Glass (PSG), Boroilicate Glass (BSG), Boron-Doped Phosphosilicate Glass (BPSG), Fluorine-Doped Silicate Glass (FSG), Tetraethyl orthosilicate (TEOS). Example ELK dielectric materials include porous organosilicate glass. In an embodiment, interconnect structure 252 includes one or more contact pads coupled to the metallization layers. The metallization layers and the contact pads may include copper (Cu), aluminum (Al), and/or titanium nitride (TiN).

Bonding layer 219 may be electrically connected to interconnect structure 252. Bonding layer 219 may include a dielectric layer 231 and one or more bonding contacts 232 distributed in dielectric layer 231. Dielectric layer 231 may include a suitable dielectric material such as silicon oxide, silicon nitride, silicon oxynitride, and/or spin-on glass (SOG). Dielectric layer 231 may be directly bonded to dielectric layer 233 through dielectric-to-dielectric bonding at bonding interface 254. Bonding contacts 232 may be directly bonded to bonding contacts 234 through metal-to-metal bonding at bonding interface 254. Electrical signals can be transmitted from bonding contacts 234 to interconnect structure 252, and further to the FEOL devices/structures of IC 236.

One or more second thermal dissipation features 242 may be disposed outside IC 236. Second thermal dissipation feature 242 may extend fully in dielectric layer 244 surrounding IC 236. As shown in FIG. 2A, second thermal dissipation feature 242 may extend in a dielectric layer 244 surrounding IC 236. The second thermal dissipation feature 242 is also referred to as thermal TDV, or denoted as tTDV. In an embodiment, second thermal dissipation feature 242 may be a via that has a square cross-section. The side length of second thermal dissipation feature 242 may be greater than the diameter of TSV 230 (e.g., or the side length of via 240-1), such that second thermal dissipation feature 242 has a larger cross-sectional area (e.g., or larger than via 240-1) which facilitates heat dissipation. In an embodiment, one end of second thermal feature 242 may be bonded to a respective bonding contact 240-2 at bonding interface 254 through direct metal-to-metal bonding. The other end of second thermal feature 242 may be in contact with second surface 256 of second semiconductor structure 250. Second thermal dissipation feature 242 may include a suitable conductive material such as copper, tungsten, aluminum, and/or a combination or an alloy. In an embodiment, dielectric layer 244 includes a suitable dielectric material such as silicon oxide, silicon nitride, silicon oxynitride, and/or spin-on glass (SOG).

One or more support structures 237 may be disposed aside from IC 236. In an embodiment, as shown in FIG. 2B, the projection of support structure 237 completely falls in the projection of IC 208 (e.g., in the x-y plane). Support structure 237 may have the same thickness (e.g., in the z-direction) as the thickness of IC 236. Support structure 237 may include a support layer 220 and a bonding layer 216 in contact with support layer 220. Support layer 220 may provide at mechanical support for IC 236, and may include a suitable material of sufficient stiffness and mechanical strength such as single-crystalline silicon, carbon, and/or polysilicon. A via 214-1, as part of a thermal dissipation structure, may extend through support layer 220. Via 214-1 is also referred to as thermal TSV, or denoted as tTSV. In an embodiment, one end of via 214-1 is in contact with a bonding contact in bonding layer 216, and the other end of via 214-1 is in contact with second surface 256 of second semiconductor structure 250. Via 214-1 may not be in contact with any active device. In an embodiment, via 214-1 may include a square cross-section in the x-y plane, such that second thermal dissipation feature 214-1 has a larger cross-sectional area (e.g., than a via having a round cross-section of the same diameter) which facilitates heat dissipation.

Bonding layer 216 may be in contact of bonding layer 212 at bonding interface 254. Bonding layer 216 may include a dielectric layer 217 and one or more bonding contacts 214-2 distributed in dielectric layer 217. In an embodiment, one end of each bonding contact 214-2 is directly bonded with bonding contact 240-2 at bonding interface 254 through metal-to-metal bonding. The other end of bonding contact 214-2 may be in contact with a respective via 214-1. In an embodiment, via 214-1 and the respective bonding contact 214-2 may together be referred to as a third thermal dissipation feature 214. In an embodiment, dielectric layer 217 includes a suitable dielectric material such as silicon oxide, silicon nitride, silicon oxynitride, and/or spin-on glass (SOG). Via 214-1 and bonding contact 214-2 may each include a suitable conductive material such as copper, tungsten, aluminum, and/or a combination or an alloy.

In an embodiment, first thermal dissipation feature 240 and second thermal dissipation feature 242 may form a first thermal dissipation structure 260. In an embodiment, first thermal dissipation feature 240 and third thermal dissipation feature 214 may form a second thermal dissipation structure 262. As shown in FIG. 2A, first and second thermal dissipation structures 260 and 262 may extend partially through IC 208 of first semiconductor structure to second surface 256 of second semiconductor structure 250. Depending on the layout of devices/structures of second semiconductor structure 250, in various embodiments, the first thermal dissipation structures may be flexibly disposed between IC 236 and support structure 237, and/or in the peripheral area of 3D semiconductor device 200.

In an embodiment, a carrier wafer 226 is attached to second semiconductor structure 250 on second surface 256 through one or more adhesive layers 224 (such as thermal glue). A cooling medium 202 may be disposed over carrier wafer 226 on the surface facing away from second semiconductor structure 250, through an adhesive layer 228 (such as thermal glue). In an embodiment, carrier wafer 226 may have desirable cooling effect. Cooling medium 202 may include a water package or any suitable packaged cooling material. Adhesive layers 224 and 228 may have desirable thermal conductivity such that the first and second thermal dissipation structures are thermally coupled to carrier wafer 226 and further cooling medium 202. Heat generated in IC 208 may then be conducted to carrier wafer 226 and/or cooling medium 202 by the first and second thermal dissipation structures, and IC 208 may be cooled.

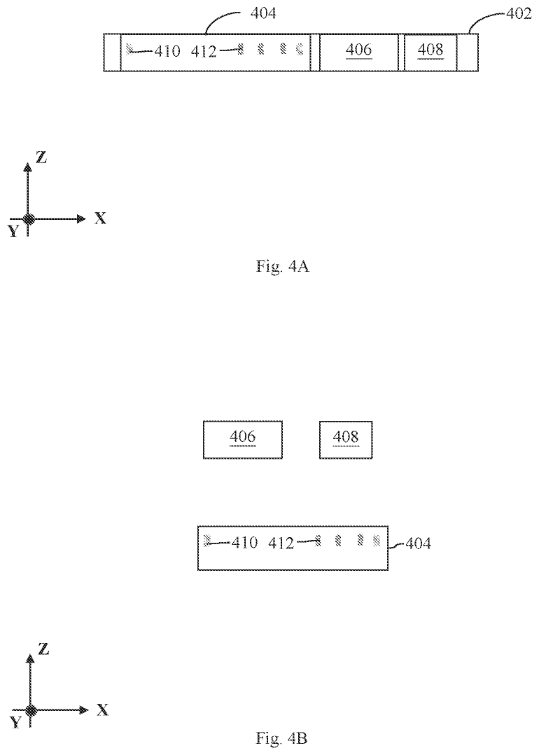

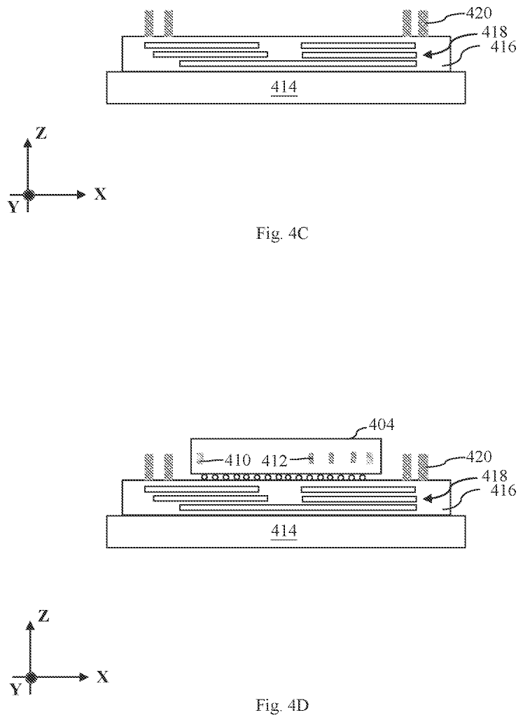

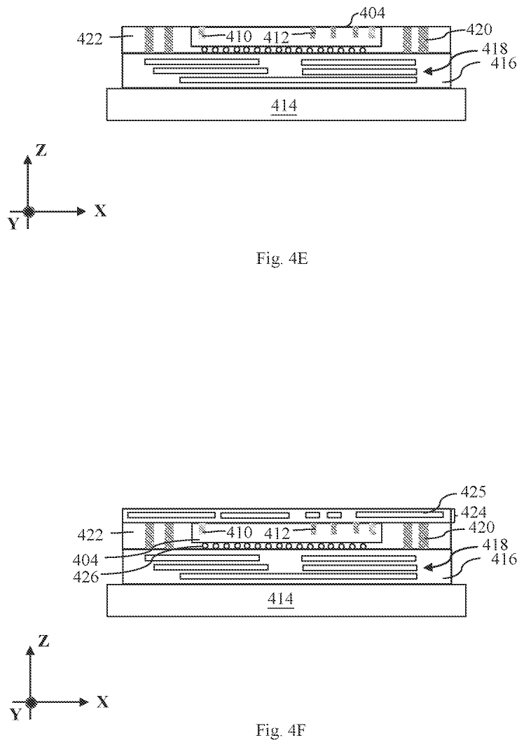

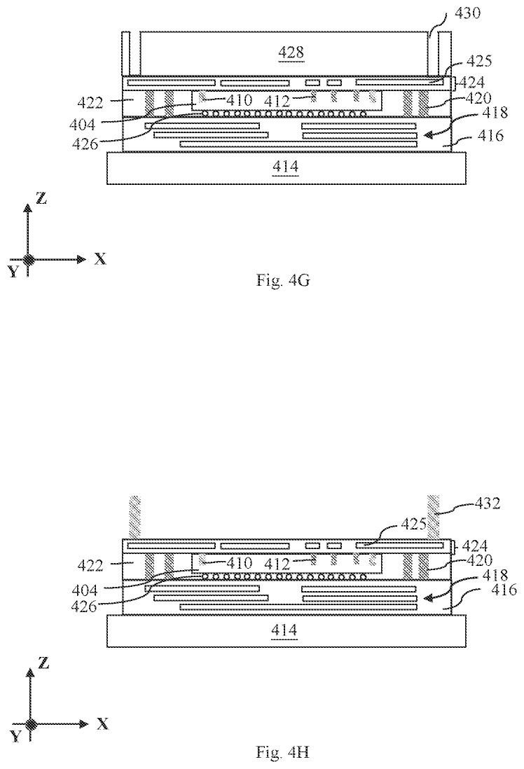

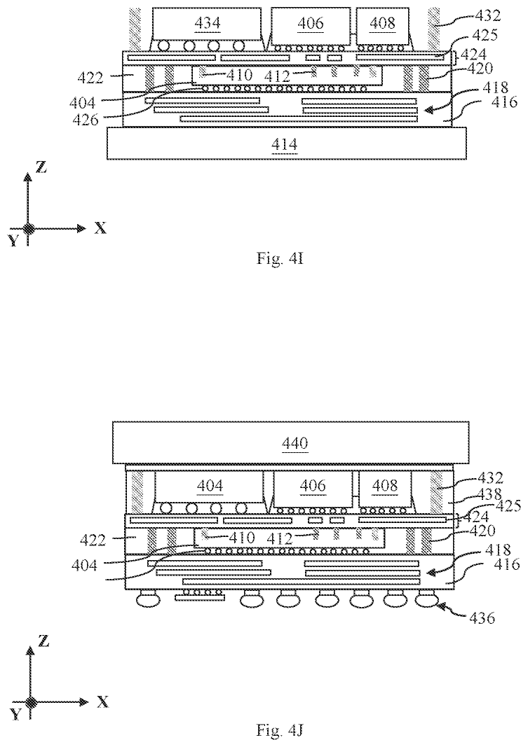

A method 300 for forming a 3D semiconductor device having a thermal dissipation structure is illustrated in the flowchart in FIG. 3. Method 300 is merely an example, and is not intended to limit the present disclosure beyond what is explicitly recited in the claims. FIGS. 4A-4J illustrate cross-sectional views of part of the semiconductor structure at different stages of a fabrication process, according to some aspects of the present disclosure. Additional operations can be provided before, during, and after the method 400, and some operations described can be replaced, eliminated, or moved around for additional embodiments of method 300. Method 300 may be employed to form 3D semiconductor device 100 or similar, and will be described in more detail below.

As shown in FIG. 3, method 300 includes a block 302 where a first via is formed in a first IC. FIG. 4A illustrates a corresponding structure.

As shown in FIG. 4A, a first via 410 is formed in an IC 404. First via 410 may extend partially in IC 404. In an embodiment, first via 410 is embedded in IC 404 such that first via 410 is not exposed on the surfaces of IC 404. For example, first via 410 is formed in a non-conductive material (e.g., a dielectric material) in IC 404, and is not conductively connected to an active device. In an embodiment, IC 404 may include connectors exposed on the bottom side for electrically connecting to a redistribution structure. Another via 412, such as a TSV, for example, is also formed in IC 404. Vias 410 and 412 may include the same conductive material such as a metal, e.g., tungsten and/or copper. In an embodiment, vias 410 and 412 are formed in the same fabrication process. The formation of vias 410 and 412 may include a patterning process that forms, in IC 404, openings that corresponding to the locations of vias 410 and 412. The patterning process may include photolithography and a suitable etching process (e.g., dry and/or wet etch). The formation of vias 410 and 412 may also include a deposition process the fills the openings with a conductive material. The deposition process may include one or more of evaporation, electroplating, electroless plating, chemical vapor deposition (CVD), and/or physical vapor deposition (PVD). Optionally, a planarization process, such as a chemical mechanical polishing (CMP) and/or a recess etch, is performed to remove excess conductive material on IC 404. Vias 410 and 412 may be formed. In an embodiment, one or more dielectric layers may be formed over vias 410 and 412. The formation of dielectric layers may include one or more deposition processes such as CVD, PVD, atomic layer deposition (ALD), or a combination thereof.

ICs 406 and 408 may also be formed. ICs 404, 406, and 408 may each be a suitable die (e.g., a memory die, a logic die, etc.). The formation of ICs 406 and 408 may include one or more patterning processes, and one or more deposition processes such as CVD. PVD, ALD, evaporation, electroplating, electroless plating, or a combination thereof. As an example, ICs 404, 406, and 408 are disposed in a same wafer/workpiece 402. In various embodiments, ICs 404, 406, and 408 may be disposed in one or more different wafers/workpieces.

As shown in FIGS. 4B, ICs 404, 406, and 408 are diced and separated through a dicing process. Meanwhile, a workpiece for bonding IC 404 onto may be prepared. As shown in FIG. 4C, the workpiece may be formed by forming a redistribution structure 416 on a carrier wafer 414, and forming one or more vias 420, such as a TMV, over redistribution structure 416. Redistribution structure 416 may include a plurality of dielectric layers and metallization layers 418 (e.g., referring back to the description of redistribution structure 106), and the fabrication of redistribution structure 416 may include one or more patterning processes, and one or more deposition processes such as CVD. PVD. ALD, evaporation, electroplating, electroless plating, or a combination thereof. In an embodiment, redistribution structure 416 may include connectors exposed on the top surface for electrically connecting metallization layers 418 and vias, while the bottom surface of redistribution structure 416 is in contact with carrier wafer 414.

In an embodiment, after redistribution structure 416 is formed, a patterned photoresist layer (not shown) is formed on the first surface of redistribution structure 416. The patterned photoresist layer may include openings exposing the connectors on redistribution structure 416. A conductive material, such as copper and/or tungsten, is then formed to fill the openings. The patterned photoresist layer may then be removed. The retained conductive material may form vias 420, which can each be a TMV, conductively connected to (e.g., in contact with) metallization layers 418 in redistribution structure 416. The patterned photoresist layer may be formed using a photolithography process. The conductive material may be deposited using one or more of electroplating, electroless plating, CVD, and/or PVD.

As shown in FIG. 4D, IC 404 may then be bonded onto redistribution structure 416. In an embodiment, IC 404 is located aside from vias 420, and may be bonded to redistribution structure 416 through soldering features. Redistribution structure 416 may include connectors, on the top surface, for electrically connecting redistribution structure 416 and IC 404 through the soldering features. In an embodiment, a plurality of soldering features 426 may be formed in contact with the respective connectors on the top surface of redistribution structure 416. IC 404 may then be aligned and disposed on the soldering features 426, such that the connectors exposed on the bottom surface of IC 404 may be electrically connected to metallization layers 418 in redistribution structure 416. Soldering features 426 may include a suitable conductive material such as Sn Pb, Ag, etc., and can be formed by a suitable process such as evaporation, electroplating, electroless plating, ball drop, and/or screen printing.

As shown in FIG. 4E, a molding layer 422 may be formed to encapsulate the structures/devices above redistribution structure 416, and a planarization process is performed to expose vias 410 and 412 in IC 404. Molding layer 422 may include a molding compound such as epoxy and/or resin. Molding layer 422 may be formed by depositing (e.g., spinning on) a layer of molding material, which is then cured to harden. A planarization process, such as a CMP and/or a recess etch, may be performed to remove excess material of IC 404, molding layer 422, and/or vias 420, to expose vias 410 and 412 on the top surface of IC 404. In an embodiment, IC 404, molding layer 422, and vias 420, may be coplanar with one another.

Referring back to FIG. 3, method 300 includes a block 304 where an interconnect routing is formed over and in contact with the first via. FIG. 4F illustrates a corresponding structure.

As shown in FIG. 4F, an interposer 424 may be formed over IC 404, molding layer 422, and vias 420. Interposer 424 may be electrically connected to IC 404, and may include one or more dielectric layers and a plurality of interconnect routings (e.g., referring back to the description of interposer 112 and interconnect routing 114-2) extending in the dielectric layers. For example, interposer 424 may include at least an interconnect routing that electrically connects via 420 with via 412, and at least an interconnect routing 425 that couples (e.g., in contact with) first via 410 and a subsequently-formed via. The dielectric layer of interposer 112 may include silicon oxide, and the interconnect routings may include a conductive material such as tungsten and/or copper. Interposer 424 may be formed by one or more patterning processes, and one or more deposition processes such as CVD, PVD, ALD, evaporation, electroplating, electroless plating, or a combination thereof. Optionally, a planarization process, such as a CMP and/or a recess etch, may be performed to remove excess material of interposer 424. It should be noted that, although not shown, interconnect routing 425 may be in contact with (or coupled to) via 410.

Referring back to FIG. 3, method 300 includes a block 306 where a second via is formed over the first IC and in contact with the interconnect routing. FIGS. 4G and 4H illustrate corresponding structures.

As shown in FIG. 4G, a patterned sacrificial layer 428 is formed on interposer 424. Patterned sacrificial layer 428 include one or more openings 430 that exposes the interconnect routing(s) that are connected to first vias 410. Patterned sacrificial layer 428 may include a dielectric material and may be formed by depositing a dielectric layer and patterning through a photolithography process and an etching process. In another embodiment, patterned sacrificial layer 428 may include photoresist and be formed by a photolithography process.

As shown in FIG. 4H, a conductive material, such as tungsten and/or copper, may be formed in openings 430 and in contact with the interconnect routing(s) that are connected to first vias 410. Patterned sacrificial layer 428 may then be removed in an etching process. A second via 432, connected to (e.g., in contact with) interconnect routing 425, can be formed. The conductive material may be formed by electroplating and/or electroless plating. In an embodiment, the conductive material may be formed by sputtering, CVD, and/or PVD. In an embodiment, first via 410, the respective interconnect routing, and second via 432 may form a thermal dissipation structure.

Referring back to FIG. 3, method 300 includes a block 308, where a second IC is bonded over the interconnect routing. FIG. 4I illustrates a corresponding structure.

As shown in FIG. 4I, a second IC (e.g., one or more of ICs 434, 406, and 408), may be bonded over interposer 424. The second IC may be disposed aside from second via 432, and may be electrically connected to interposer 424 through soldering features. In an embodiment, the second IC include a memory die, such as DRAM (e.g., IC 434). IC 404 may then be bonded onto redistribution structure 416. In an embodiment, interposer 424 may include connectors, on the top surface, for electrically connecting interposer 424 with the soldering features that connect ICs 434, 406, and 408. In an embodiment, a plurality of soldering features may be formed in contact with the respective connectors on the top surface of interposer 424. ICs 434, 406, and 408 may then be aligned and disposed on the soldering features, such that the connectors exposed on the bottom surface of ICs 434, 406, and 408 may be electrically connected to respective routing interconnects in interposer 424. The soldering features may include a suitable conductive material such as Sn Pb, Ag, etc., and can be formed by a suitable process such as evaporation, electroplating, electroless plating, ball drop, and/or screen printing.

Referring back to FIG. 3, method 300 includes a block 310, where a molding layer is formed around the second IC and the second via. FIG. 4J illustrates a corresponding structure.

As shown in FIG. 4J, a molding layer 438 is formed to encapsulate the second IC (e.g., ICs 434, 406, and/or 408) and second vias 432. Molding layer 438 may include a molding compound such as epoxy and/or resin. Molding layer 438 may be formed by a suitable process such as deposition and curing. A planarization process, such as a CMP and/or a recess etch, may be performed to remove excess material of molding layer 438. In an embodiment, IC 404, molding layer 422, and vias 420, may be coplanar with one another.

In an embodiment, a cooling medium 440 is attached to the top surface of the second IC and molding layer 438 though an adhesive layer. The cooling medium may include a suitable cooling material such as water package. In an embodiment, the adhesive layer may be applied on the top surface of the second IC and molding layer 438, and cooling medium 440 is mounted on the adhesive layer.

In an embodiment, carrier wafer 414 is removed to expose redistribution structure 416, and a plurality of soldering features 436 may be formed in contact with the respective connectors on the bottom surface of redistribution structure 416. Carrier wafer 414 may be removed by a suitable etching process (e.g., dry and/wet etch) and/or a planarization process such as CMP. Soldering features 436 may include a suitable conductive material such as Sn Pb, Ag, etc., and can be formed by a suitable process such as evaporation, electroplating, electroless plating, ball drop, and/or screen printing.

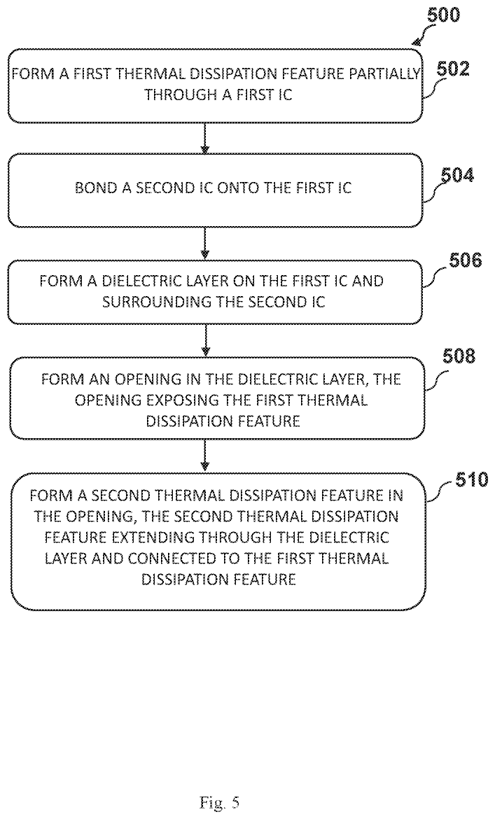

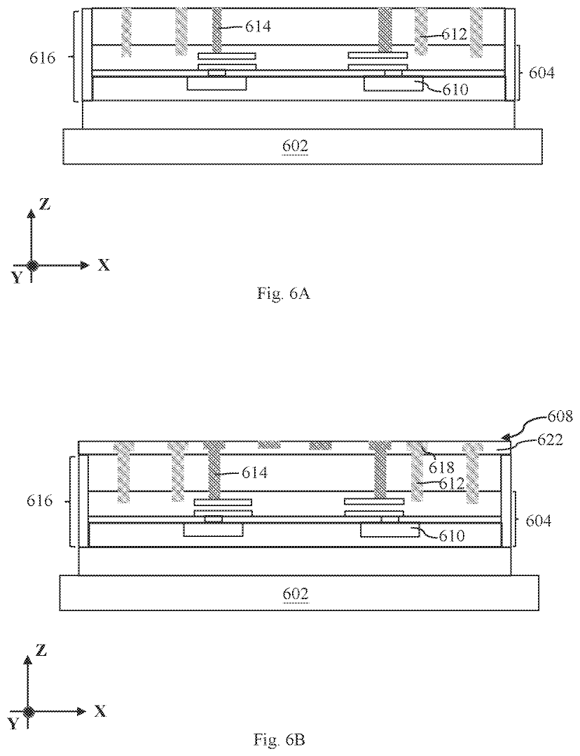

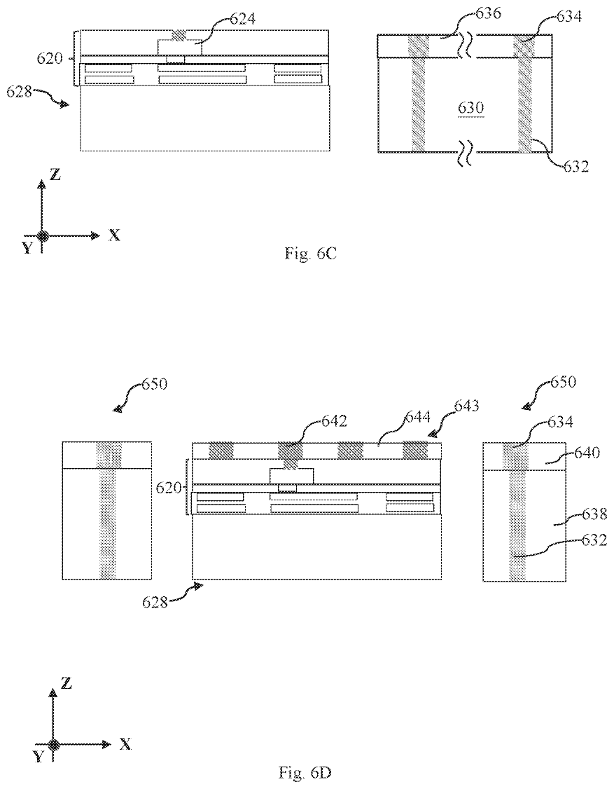

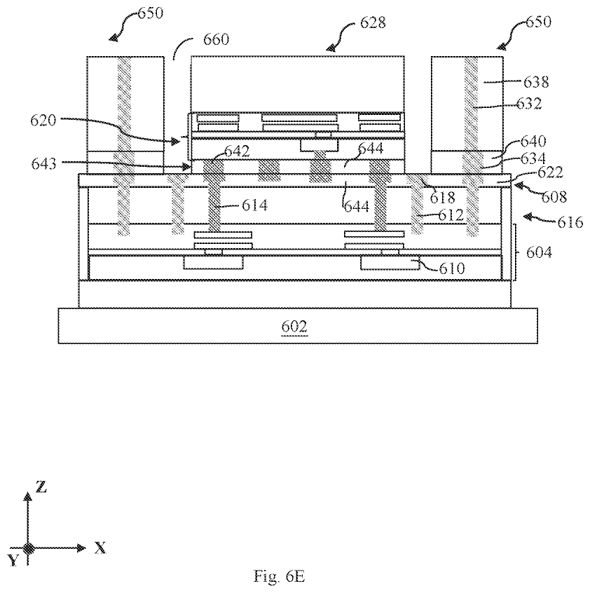

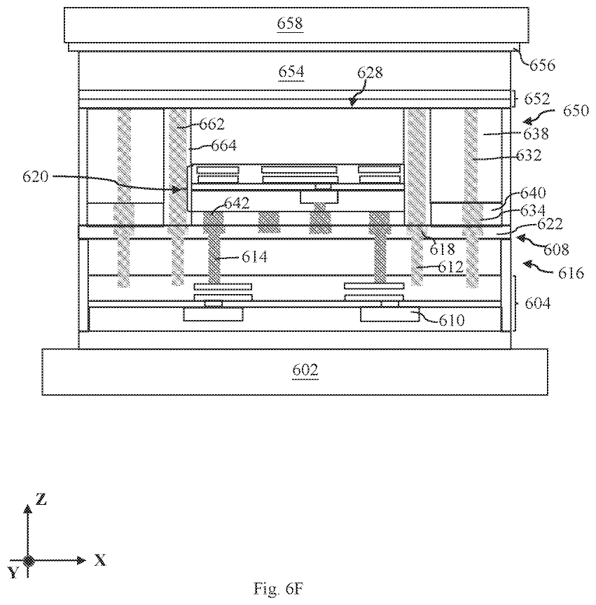

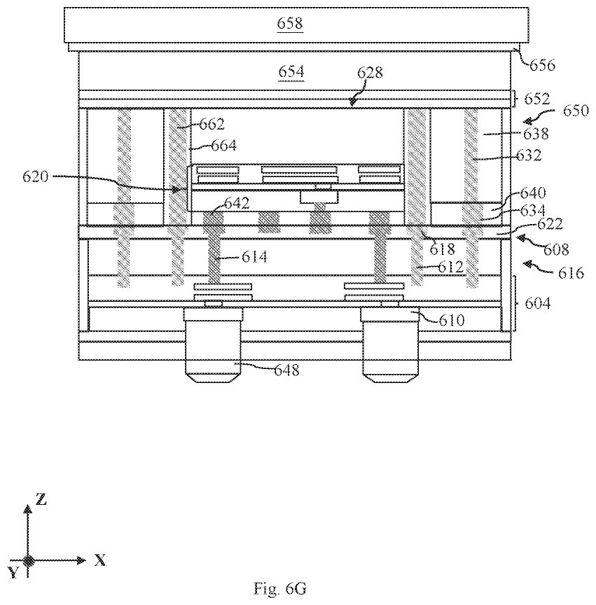

A method 500 for forming a 3D semiconductor device having one or more thermal dissipation structures is illustrated in the flowchart in FIG. 5. Method 500 is merely an example, and is not intended to limit the present disclosure beyond what is explicitly recited in the claims. FIGS. 6A-6J illustrate cross-sectional views of part of the semiconductor structure at different stages of a fabrication process, according to some aspects of the present disclosure. Additional operations can be provided before, during, and after the method 500, and some operations described can be replaced, eliminated, or moved around for additional embodiments of method 500. Method 500 may be employed to form 3D semiconductor device 200 or similar, and will be described in more detail below.

As shown in FIG. 5, method 500 includes a block 502 where a first thermal dissipation feature is formed fully through a first IC. FIGS. 6A and 6B illustrate a corresponding structure.

As shown in FIG. 6A, one or more vias 612 and 614 may be formed partially through an IC 616. IC 616 may be a suitable die (e.g., a memory die, a logic die, etc.). IC 616 may include a plurality of FEOL devices/structures and an interconnect structure 604 electrically connected to the FEOL devices/structures. Interconnect structure 604 may include a plurality of dielectric layers and metallization layers. For example, interconnect structure 604 may include a contact pad 610 that is conductively connected to a metallization layer. Contact pad 610 may further be connected to a UBM feature for electrical connected with an external circuit, as will be described below. In an embodiment, IC 616 may be disposed on a carrier substrate 602. Optionally, one or more buffer layers may be disposed between IC 616 and carrier substrate 602. In an embodiment, IC 616 may be bonded/glued onto carrier substrate 602. Carrier substrate 602 may be any suitable material that can provide mechanical strength and stiffness to IC 616 and interconnect structure 604. For example, carrier substrate 602 may include silicon, quartz, glass, and/or SOG. The formation of IC 616 and interconnect structure 604 may include one or more patterning processes, and one or more deposition processes such as CVD, PVD, ALD, evaporation, electroplating, electroless plating, or a combination thereof.

Vias 612 and 614 can be formed partially through IC 616. For example, vias 612 and 614 may extend partially through interconnect structure 604. In an embodiment, via 612 may not be in contact with any active devices in IC 616. For example, via 612 may extend in a dielectric material and/or silicon in IC 616. In an embodiment, vias 614 may be electrically connected to (e.g., in contact with) interconnect structure 604 (e.g., the metallization layers in interconnect structure 604). Vias 612 and 614 may include a same conductive material such as copper and/or tungsten. In an embodiment, vias 612 and 614 are formed in the same fabrication process. The formation of vias 612 and 614 may include a patterning process that forms openings that corresponding to the locations of vias 612 and 614. The openings may extend partially in interconnect structure 604. The patterning process may include photolithography and a suitable etching process (e.g., dry and/or wet etch). The formation of vias 612 and 614 may also include a deposition process the fills the openings with a conductive material. The deposition process may include one or more of evaporation, electroplating, electroless plating, CVD, and/or PVD. Optionally, a planarization process, such as a CMP and/or a recess etch, is performed to remove excess conductive material on IC 616 and/or to expose vias 612 and 614.

As shown in FIG. 6B, a bonding layer 608 may be formed over IC 616. Bonding layer 608 may include a dielectric layer 622 and a plurality of bonding contacts 618 distributed in dielectric layer 622. Bonding contact 618 may be landed on, respectively, vias 612 and 614. In an embodiment, bonding contact 618 are exposed at the top surface (e.g., facing away from IC 616) of bonding layer 608. In an embodiment, bonding contact 618 and the respective via 612 may form a first thermal dissipation feature. In an embodiment, dielectric layer 622 includes silicon oxide, and bonding contacts 618 include copper and/or tungsten. The formation of bonding layer 608 may include a patterning process which includes photolithography and a suitable etching process (e.g., dry and/or wet etch). The formation of bonding layer 608 may also include one or more deposition processes such as evaporation, electroplating, electroless plating, CVD, ALD, and/or PVD. Optionally, a planarization process, such as a CMP and/or a recess etch, is performed to remove excess conductive material on bonding layer 608 and/or to expose bonding contacts 618.

Meanwhile, an IC 628 and one or more support structures 650 may be prepared. As shown in FIGS. 6C and 6D. IC 628 may include a plurality of FEOL devices/structures and an interconnect structure 620, and may be diced to a size that's smaller than IC 616 (e.g., referring back to the description of FIG. 1B). IC 628 may be a suitable die (e.g., a memory die, a logic die, etc.). Interconnect structure 620 may be electrically connected to the FEOL devices/structures of IC 628 and may include a plurality of dielectric layers and metallization layers. The fabrication of IC 628 may be referred to those of IC 616, and the description is not repeated herein.

A bonding layer 643 may be formed over and electrically connected to interconnect structure 620. Bonding layer 643 may include a dielectric layer 644 and a plurality of bonding contacts 642 distributed in dielectric layer 644. In an embodiment, the locations of bonding contacts 642 may correspond to the locations of bonding contacts 618 that are connected to vias 614. The materials and fabrication of bonding layer 643 may be referred to those of bonding layer 608, and the detailed description is not repeated herein.

Support structure 650 may be formed by dicing a support wafer with a bonding layer into a plurality of smaller pieces. As shown in FIG. 6C, one or more vias 632 can be formed in a support wafer 630, e.g., a silicon wafer. Vias 632 may extend through support wafer 630 and may be exposed at the top surface of support wafer 630. In an embodiment, vias 632 may include a conductive material such as copper and/or tungsten, and the formation of vias 632 includes a patterning process and a deposition process such as evaporation, electroplating, electroless plating, CVD, and/or PVD.

A bonding layer may be formed over and in contact with support wafer 630. The bonding layer may include a dielectric layer 636 and a plurality of bonding contacts 634 distributed in dielectric layer 636. Each bonding contact 634 may be landed on a respective via 632, and may be exposed on the top surface of the bonding layer. The materials and fabrication of the bonding layer may be referred to those of bonding layer 608, and the detailed description is not repeated herein.

Support wafer 630 with the bonding layer may then be diced into smaller pieces. Each smaller piece may be a support structure 650. As shown in FIG. 6D, support structure 650 may include a support layer 638, one or more vias 632 extending through support layer 638, a dielectric layer 640, and one or more bonding contacts 634 each landed on a respective via 632. In an embodiment, the size of support structure 650 may be determined based on the size of IC 616 and IC 628 such that the projections of IC 628 and support structure(s) 650 may fall in the projection of IC 616. In an embodiment, the thickness of support structure 650 is at least substantially the same as the total thickness of IC 628 and bonding layer 643.

Referring back to FIG. 5, method 500 includes a block 504 where a second IC is bonded onto the first IC. FIG. 6E illustrates a corresponding structure.

As shown in FIG. 6E, IC 628 may be bonded onto IC 616 (or bonding layer 608) through bonding layer 643. Bonding layer 643 may be in contact with bonding layer 608 at a bonding interface. Specifically, bonding contacts 642 may each be bonded to a respective bonding contact 618 through metal-to-metal bonding, and dielectric layer 644 is bonded to dielectric layer 622 through dielectric-to-dielectric bonding.

In an embodiment, support structures 650 may each be bonded onto IC 616 at the bonding interface. Specifically, bonding contacts 634 may each be bonded to a respective bonding contact 618 through metal-to-metal bonding, and dielectric layer 640 is bonded to dielectric layer 622 through dielectric-to-dielectric bonding. Support structures 650 may be located aside from IC 628. That is, bonding contact 634 may be in contact with a respective first thermal dissipation feature. In an embodiment, space 660 may be formed around IC 628 (e.g., between IC 628 and a support structure 650).

Referring back to FIG. 5, method 500 includes a block 506 where a dielectric layer is formed on the first IC and surrounding the second IC. FIG. 6F illustrates a corresponding structure.

As shown in FIG. 6F, a dielectric layer 664 may be formed on IC 616 and surrounding IC 628. In an embodiment, dielectric layer 664 is formed in space 660. Dielectric layer 664 may be deposited on the side surfaces of support structures 650 and IC 628. Dielectric layer 664 may include a dielectric material such as silicon oxide. Dielectric layer 664 may be formed by depositing a dielectric material in space 660. The dielectric material may be deposited by CVD. PVD, and/or ALD.

Referring back to FIG. 5, method 500 includes a block 508 where an opening is formed in the dielectric layer, the opening exposing the first thermal dissipation feature. FIG. 6F illustrates a corresponding structure.

In an embodiment, a recess etch may be performed to form an opening in dielectric layer 664 that exposes bonding contact 618 at the bottom of the opening (e.g., on the surface of bonding layer 608). That is, the opening may expose a respective thermal dissipation feature at the bonding interface.

Referring back to FIG. 5, method 500 includes a block 510 where a second thermal dissipation feature is formed in the opening, the second thermal dissipation feature extending through the dielectric layer and connected to the first thermal dissipation feature. FIG. 6F illustrates a corresponding structure.

As shown in FIG. 6F, a conductive material may be deposited in the opening. The conductive material may include copper and/or tungsten. A second thermal dissipation feature 662 may be formed in the opening and in contact with a respective first thermal dissipation feature at the bonding interface. Second thermal dissipation feature 662 and the respective first thermal dissipation feature may form a thermal dissipation structure. The deposition process may include one or more of evaporation, electroplating, electroless plating, CVD, and/or PVD.

In an embodiment, each via 632 and the respective bonding contact 634 may form a third thermal dissipation feature. The third thermal dissipation feature and the respective first thermal dissipation feature may form another thermal dissipation structure.

In an embodiment, a carrier wafer 654 is attached to the top surfaces of IC 628, dielectric layer 664, and support structures 650 through one or more adhesive layers 652, such as thermal glue. Adhesive layers 652 may have sufficiently high thermal conductivity such that heat transmitted by the thermal dissipation structures may be transmitted to carrier wafer 654 by adhesive layers 652. In an embodiment, carrier wafer 654 may also have desirable cooling effect. For example, carrier wafer 654 may be a silicon wafer, glass, or SOG.

In an embodiment, as shown in FIG. 6G, carrier substrate 602 is removed, one or more passivation layers may be formed and patterned over the bottom surface of interconnect structure 604. A plurality of connecting structures 648 may be formed over the passivation layers and in contact with the respective connectors on the bottom surface of interconnect structure 604. For example, connecting structures 648 may be electrically connected to contact pads 610. Connecting structures 648 may each include a UBM and a soldering feature coupled to the UBM. The passivation layers may include a suitable insulating material such as a dielectric material, spin-on-glass, epoxy, and/or polyimide. The deposition of the passivation layers may include CVD, PVD, ALD, and/or sputtering. The patterning of the passivation layers may include photolithography and a suitable etching process. Connecting structures 648 may include suitable conductive materials such as titanium, copper, Sn Pb, Ag, etc., and can be formed by suitable process such as CVD. PVD, sputtering, evaporation, electroplating, electroless plating, ball drop, and/or screen printing.

Optionally, a cooling medium 658 may be attached to the top surface of the carrier wafer 654 though an adhesive layer 656 (e.g., a thermal glue). The cooling medium may include a suitable cooling material such as water package. In an embodiment, adhesive layer 656 may have desirably high thermal conductivity such that heat generated in (or transmitted to) carrier wafer 654 can be further transmitted to cooling medium 658. Cooling medium 658 and carrier wafer 654, e.g., including adhesive layers 652 and 656, may thus function as a cooling structure

In one aspect of the present disclosure, an integrated semiconductor device is provided. The integrated semiconductor device includes a first semiconductor structure having a first IC, and a second semiconductor structure stacked above the first semiconductor structure and having a second IC. The second semiconductor structure has a first surface facing the first semiconductor structure and a second surface facing away from the first semiconductor structure. The integrated semiconductor device also includes a thermal dissipation structure having a first portion partially through the first IC and a second portion fully through the second semiconductor structure and exposed at the second surface of the second semiconductor structure. The second portion may be outside of the second IC.

In an embodiment, the integrated semiconductor device further includes a cooling structure disposed on the second surface of the second semiconductor structure. The second portion of the thermal dissipation structure is thermally coupled with the cooling structure. In an embodiment, the integrated semiconductor device may further include an interposer stacked between the first semiconductor structure and the second semiconductor structure. The interposer includes an interconnect routing electrically coupling the first IC and the second IC, and the thermal dissipation structure includes a third portion extending through the interposer and connecting the first and second portions. In an embodiment, the second semiconductor structure comprises an epoxy molding layer around the second IC, and the second via portion is completely through the epoxy molding layer. In an embodiment, the second semiconductor structure comprises a dielectric layer around the second IC, and the second via portion is completely through the dielectric layer. In an embodiment, the second semiconductor structure includes a silicon layer aside the second IC, and the second via portion is completely through the silicon layer.

In an embodiment, the first portion includes a first via and the second portion includes a second via. In an embodiment, the first via and the second via each has a square cross-section. In an embodiment, the first via and the second via each comprises copper. In an embodiment, the cooling structure comprises at least one of a cooling medium or a carrier wafer.

Another aspect of the present disclosure provides a method for forming an integrated semiconductor device. The method includes forming a first via in a first IC, forming an interconnect routing over and in contact with the first via, forming a second via over the first IC and in contact with the interconnect routing, bonding a second IC over the interconnect routing, and forming a molding layer around the second IC and the second via. In an embodiment, the forming of the interconnect routing comprises forming an interposer over the first IC, and the interconnect routing is located in the interposer. In an embodiment, the forming of the second via includes forming a photoresist layer over the interposer, patterning the photoresist layer to form an opening that exposes the interconnect routing, forming the second via in the opening using electroplating, and removing the photoresist layer. In an embodiment, the method further includes forming a soldering structure over the interposer. The bonding of the second IC may include bonding the second IC on the soldering structure. In an embodiment, the method further includes disposing a cooling structure over the second IC. The second via may be thermally coupled to the cooling structure.

Another aspect of the present disclosure provides a method for forming an integrated semiconductor device. The method includes forming a first thermal dissipation feature partially through a first IC, bonding a second IC onto the first IC, forming a dielectric layer on the first IC and surrounding the second IC, forming an opening in the dielectric layer, the opening exposing the first thermal dissipation feature, and forming a second thermal dissipation feature in the opening. The second thermal dissipation feature may extend through the dielectric layer and connected to the first thermal dissipation feature. In an embodiment, the first thermal dissipation feature includes a first via and a first bonding contact landing on the first via, and the second thermal dissipation feature includes a second via landing on the first bonding contact. In an embodiment, the method further includes forming the first bonding contact over the first via prior to the bonding of the second IC onto the first IC. In an embodiment, the method further includes forming a third thermal dissipation feature in the first IC, and forming a fourth thermal dissipation feature in a support structure. The method also include bonding the support structure on the first IC and aside the second IC, such that the third thermal dissipation feature is in contact with the fourth thermal dissipation feature. In an embodiment, the method further includes disposing a cooling structure over the second IC. The second thermal dissipation feature may be thermally coupled to the cooling structure.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An integrated semiconductor device, comprising:
a first semiconductor structure comprising a first integrated circuit (IC);
a second semiconductor structure stacked above the first semiconductor structure and comprising a second IC, the second semiconductor structure having a first surface facing the first semiconductor structure and a second surface facing away from the first semiconductor structure; and
a thermal dissipation structure having a first portion partially through the first IC and a second portion fully through the second semiconductor structure and exposed at the second surface of the second semiconductor structure, the second portion being outside of the second IC.

2. The integrated semiconductor device of claim 1, further comprising:
a cooling structure disposed on the second surface of the second semiconductor structure, wherein the second portion of the thermal dissipation structure is thermally coupled with the cooling structure.

3. The integrated semiconductor device of claim 1, further comprising:
an interposer stacked between the first semiconductor structure and the second semiconductor structure, wherein the interposer comprises an interconnect routing electrically coupling the first IC and the second IC, and wherein the thermal dissipation structure includes a third portion extending through the interposer and connecting the first and second portions.

4. The integrated semiconductor device of claim 1, wherein:
the second semiconductor structure comprises an epoxy molding layer around the second IC; and
the second via portion is completely through the epoxy molding layer.

5. The integrated semiconductor device of claim 1, wherein:
the second semiconductor structure comprises a dielectric layer around the second IC; and
the second via portion is completely through the dielectric layer.

6. The integrated semiconductor device of claim 1, wherein:
the second semiconductor structure comprises a silicon layer aside the second IC; and
the second via portion is completely through the silicon layer.

7. The integrated semiconductor device of claim 1, wherein the first portion includes a first via and the second portion includes a second via.

8. The integrated semiconductor device of claim 7, wherein the first via and the second via each has a square cross-section.

9. The integrated semiconductor device of claim 7, wherein the first via and the second via each comprises copper.

10. The integrated semiconductor device of claim 2, wherein the cooling structure comprises at least one of a cooling medium or a carrier wafer.

11. A method for forming an integrated semiconductor device, comprising:
forming a first via in a first integrated circuit (IC);
forming an interconnect routing over and in contact with the first via;
forming a second via over the first IC and in contact with the interconnect routing;
bonding a second IC over the interconnect routing; and
forming a molding layer around the second IC and the second via.

12. The method of claim 11, wherein:
the forming of the interconnect routing comprises forming an interposer over the first IC; and
the interconnect routing is located in the interposer.

13. The method of claim 12, wherein the forming of the second via comprises:
forming a sacrificial layer over the interposer;
patterning the sacrificial layer to form an opening that exposes the interconnect routing;
forming the second via in the opening using electroplating; and
removing the sacrificial layer.

14. The method of claim 12, further comprising forming a soldering structure over the interposer,
wherein the bonding of the second IC comprises bonding the second IC on the soldering structure.

15. The method of claim 11, further comprising disposing a cooling structure over the second IC,
wherein the second via is thermally coupled to the cooling structure.

16. A method for forming an integrated semiconductor device, comprising:
forming a first thermal dissipation feature partially through a first integrated circuit (IC);
bonding a second IC onto the first IC;
forming a dielectric layer on the first IC and surrounding the second IC;
forming an opening in the dielectric layer, the opening exposing the first thermal dissipation feature; and
forming a second thermal dissipation feature in the opening, the second thermal dissipation feature extending through the dielectric layer and connected to the first thermal dissipation feature.

17. The method of claim 16, wherein the first thermal dissipation feature includes a first via and a first bonding contact landing on the first via, and the second thermal dissipation feature includes a second via landing on the first bonding contact.

18. The method of claim 17, further comprising forming the first bonding contact over the first via prior to the bonding of the second IC onto the first IC.

19. The method of claim 17, further comprising:
forming a third thermal dissipation feature in the first IC;
forming a fourth thermal dissipation feature in a support structure; and
bonding the support structure on the first IC and aside the second IC, such that the third thermal dissipation feature is in contact with the fourth thermal dissipation feature.

20. The method of claim 16, further comprising disposing a cooling structure over the second IC,
wherein the second thermal dissipation feature is thermally coupled to the cooling structure.
